(19) United States
(12) Patent Application Publication
(10) Pub. No.: US 2025/0386439 A1
(43) Pub. Date: Dec. 18, 2025

(54) METHODS AND PROCESSES FOR STRETCHABLE MULTI-LAYER CIRCUITS AND SYSTEMS AND METHODS OF USE THEREOF

(71) Applicant: Meta Platforms Technologies, LLC, Menlo Park, CA (US)

(72) Inventors: Jonathan Wilkerson, San Francisco, CA (US); Simon Jacobs, Lucas, TX (US); Zhenzhen Shen, Kirkland, WA (US); Jitkanya Wong, Everett, WA (US); Katherine Coles, San Jose, CA (US); Weiping Dou, Cupertino, CA (US); Jiang Zhu, Cupertino, CA (US); Eduardo Valarezo, Lynnwood, WA (US); Benjamin Cook, Woodinville, WA (US)

(21) Appl. No.: 19/241,226

(22) Filed: Jun. 17, 2025

Related U.S. Application Data
(60) Provisional application No. 63/661,000, filed on Jun. 17, 2024.

(51) Int. Cl. H05K 3/18; H05K 1/02; H05K 1/03; H05K 3/40

(52) U.S. Cl. CPC H05K 3/181; H05K 1/024; H05K 1/0283; H05K 1/0373; H05K 1/0393; H05K 3/4038; H05K 2201/068; H05K 2201/1006; H05K 2201/10098; H05K 2203/072; H05K 2203/107

(57) ABSTRACT

A wearable device of the subject technology includes a flexible printed circuit (FPC) including an elastomer material, and one or more dopants included in the elastomer material to be activated in response to being irradiated by light to cause formation of a first metallic seed on an exterior surface of the elastomer material. The first metallic seed layer is configured to be electroless plated to connect one or more electrical circuits to form one or more electrical circuits or antennas.

### CROSS-REFERENCE TO RELATED APPLICATIONS

The present disclosure is related and claims priority under 35 USC § 119 (e) to U.S. Provisional Application No. 63/661,000, entitled “METHODS AND PROCESSES FOR STRETCHABLE MULTI-LAYER CIRCUITS AND SYSTEMS AND METHODS OF USE THEREOF,” filed on Jun. 17, 2024, the content of which is herein incorporated by reference, in its entirety, for all purposes.

### TECHNICAL FIELD

The present disclosure generally relates to flexible electronic circuits, and more particularly, to methods and processes for stretchable multi-layer circuits and systems and methods of use thereof.

### BACKGROUND

Flexible circuits (e.g., antennas) are mainly limited to flexible printed circuit boards (FPCs) and some antenna in textile attempts in academia. Laser direct structuring (LDS) applications are generally limited to rigid materials, although application of LDS on elastomers implementing traces on a single layer has been published. Antennas are commonly built on rigid structures using the LDS process.

Current flexible antenna implementations in FPC are not integrated with wearable devices (e.g., wristband, gloves, etc.) and have low reliability in target user environments across bending and stretching due to material stack up and construction. Reliable flexible materials for wearable band structures have to be able to withstand high cycle levels (e.g., 20k cycles or more) at wrist bend radii. FPC antenna implementations could be costly to produce and difficult to reliably integrate with wearable band structures without damage. Currently, there are no reliable, flexible ways to connect FPC antenna implementations through flexible silicone over molding to active circuitry, or textile implementations in academia.

### SUMMARY

In some aspects, the subject disclosure relates to a wearable device consisting of an FPC including an elastomer material and one or more dopants included in the elastomer material to be activated in response to being irradiated by light to cause formation of a first metallic seed layer on or under a surface of the elastomer material. The first metallic seed layer of the one or more metallic seed layers is configured to be electroless plated to form one or more electrical circuits or antennas.

In some other aspects, the subject disclosure relates to a method comprising forming an elastomer material including one or more dopants and activating the one or more dopants via one or more types of light to form a first metallic seed layer of one or more metallic seed layers on an exterior surface of the elastomer material. The method also includes electroless plating the first metallic seed layer of the one or more metallic seed layers, by irradiating a first amount of light to an exterior surface of the elastomer material, to connect one or more electrical circuits coupled to the exterior surface of the elastomer material. The method further includes forming one or more vias in an interior portion of the elastomer material, by irradiating a second amount of light, to connect one or more circuits coupled to one or more FPCs.

In yet other aspects, the subject disclosure relates to an FPC including an elastomer material and/or more dopants included in the elastomer material and configured to be activated in response to light irradiation to cause formation of a first metallic seed on or under a surface of the elastomer material. The first metallic seed layer is configured to be electroless plated to form one or more electrical circuits or antennas.

### BRIEF DESCRIPTION OF THE DRAWINGS

To easily identify the discussion of any particular element or act, the most significant digit or digits in a reference number refer to the figure number in which that element is first introduced.

FIG. 1 is a schematic diagram illustrating a cross-sectional view of an example of a stretchable multi-layer metallized elastomeric system, according to some aspects of the subject technology.

FIG. 2A and FIG. 2B are schematic diagrams illustrating a top view and a cross-sectional view of a section of a possible implementation of a flexible multi-layer elastomeric circuit and antenna system, according to some aspects of the subject technology.

FIG. 3A and FIG. 3B are schematic diagrams illustrating top views of an example of doped elastomeric samples produced by the subject technology showing effects of copper-chromite particle size on the texture of the sample.

FIG. 4 is a chart illustrating plots of stress-strain relationship of liquid silicone rubber formulations with dopant loadings from 0% to 50% produced by the subject technology.

FIG. 5A and FIG. 5B are schematic diagrams illustrating top and cross-sectional views of a metallized elastomeric via formed by the subject technology.

FIG. 6 is a schematic diagram illustrating surface texture and roughness after laser direct sintering and electroless metallization of an antenna and transmission line by the subject technology.

FIG. 7 is a flow diagram illustrating an example of a process for providing a stretchable two-layer system, according to some aspects of the subject technology.

FIG. 8A and FIG. 8B are schematic diagrams illustrating two cross-section views of a multi-layer metallized elastomeric circuit and multi-chip module, according to some aspects of the subject technology.

FIG. 9A and FIG. 9B are charts illustrating plots of antenna efficiency and return loss versus frequency for a sample flexible antenna designed and fabricated in the subject technology.

FIG. 10A, FIG. 10B, FIG. 10C and FIG. 10D are charts illustrating permittivity and dielectric loss control in commercial communications frequency bands via dopant percentage, according to some aspects of the subject technology.

FIG. 11 is a chart illustrating dielectric loss reduction in commercial cellular frequency bands through dopant percentage loading, in another aspect of the subject technology.

FIG. 12 is a chart illustrating dielectric permittivity tuning in commercial cellular frequency bands through dopant percentage loading, in another aspect of the subject technology.

FIG. 13 is a flow diagram illustrating an example of a process for providing a stretchable multi-layer system, according to some aspects of the subject technology.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

The detailed description set forth below describes various configurations of the subject technology and is not intended to represent the only configurations in which the subject technology may be practiced. The detailed description includes specific details for the purpose of providing a thorough understanding of the subject technology. Accordingly, dimensions may be provided in regard to certain aspects as non-limiting examples. However, it will be apparent to those skilled in the art that the subject technology may be practiced without these specific details. In some instances, well-known structures and components are shown in block diagram form in order to avoid obscuring the concepts of the subject technology.

It is to be understood that the present disclosure includes examples of the subject technology and does not limit the scope of the included clauses. Various aspects of the subject technology will now be disclosed according to particular but non-limiting examples. Various embodiments described in the present disclosure may be carried out in different ways and variations, and in accordance with a desired application or implementation.

In the following detailed description, numerous specific details are set forth to provide a full understanding of the present disclosure. It will be apparent, however, to one ordinarily skilled in the art, that embodiments of the present disclosure may be practiced without some of the specific details. In other instances, well-known structures and techniques have not been shown in detail so as not to obscure the disclosure.

In some aspects, the subject technology is directed to methods and processes for stretchable multi-layer circuits and systems and methods of use thereof. In some implementations, the subject technology leverages the material properties of dielectrics, specifically, permittivity and dielectric loss (e.g., loss tangent), which play a significant role in antenna size, bandwidth, and efficiency. For example, by using custom elastomeric materials, the permittivity and dielectric loss can be tuned via dopants within specific commercial frequency bands such as cellular, Wi-Fi, and global navigation satellite System (GNSS) bands to achieve optimal antenna efficiency and miniaturization for these applications. In some implementations, dopants can be activated via infrared and ultra-violet (UV) light to form metallic seed layers embedded in and on the surface of an elastomer. In some implementations, the elastomer can be electroless plated with metal to a desired thickness for the formation and linkage of planar electrical circuits, devices, and antennas.

In some aspects, the subject technology uses electroless metal for metallization or can use electroplating after electroless plating to quickly plate desired metal structures to an additional thickness. Electroplating versus industry standard electroless plating has additional benefits of stress relief and better planarization for bendable, electronic circuits and antenna designs. In some implementations, copper can be used and an initial electroless metal due to its high yield strength and excellent conductivity; however, the subject technology is not limited to copper and nickel or other electroless metals can be used as well. In some implementations, metallized structures can be passivated with electroless nickel and immersion gold or plated with silver then gold or other high yield strength passivating materials to further enhance the bendability of the structure with higher tensile strength. In some implementations, metal thickness can be increased to enhance tensile load handling up to the adhesion force of the metal on the doped elastomer achieving stretch in excess of about 20%, which is significantly higher than the current value of about 6%. In some implementations, an additional layer of silicone encapsulant can be used as an alternative passivation.

In another aspect of the subject technology, the disclosed elastomer materials allow electrical circuits, structures, and antennas to be formed in a flexible material (e.g., wristband) with high reliability. In addition to high adhesion, flexible surface metallization and high aspect ratio, flexible vias can be formed directly in the elastomer and connected to circuits embedded within the elastomer. Examples of such circuits include FPCs, printed circuit boards (PCBs), system-in-package (SiP) modules, and integrated circuits (ICs). In some implementations, vias in elastomer can be accomplished through micro-molding and UV or infra-red (IR) laser exposure to activate the dopant, followed by electroless plating with optional electroplating. In some implementations, via structures may also be formed by direct UV drilling to a metal pad on the embedded circuit, where the UV power is increased to activate the dopant, allowing flexible vias with aspect rations of about 5:1 or even 10:1 to be achieved in elastomer. In some implementations, via structures may also be formed with direct IR drilling, with reduced aspect ratio. In some implementations, elastomer surface metallization and via structures directly connected to embedded circuitry can be used to build flexible wireless communications systems, capacitive and resistive XR input circuits, and other circuit elements directly in a flexible band.

In other aspects of the subject technology, bendable, flexible and stretchable antennas can be fabricated in flexible materials (e.g., wristbands) using over-molded FPC with optional SiPs. These antennas can be reliably connected to an FPC or SiP due to the flexible metallization embedded in elastomer, through flexible via through elastomer, or multilayer metallized elastomer constructions to allow capacitive proximity feeds. In some implementations, patch, monopole, planar inverted F antenna (PIFA), inverted F antenna (IFA), dipole, and other antenna designs can be made to withstand high stretch (e.g., greater than 10%) without cracking through subtractive honeycomb design. In some implementations, metal is selectively removed to form thin strips less than the critical bending radius. In some implementations, strips are connected through short bridges at less than about 90-degree angles to prevent breaking, also in thin strips. In some implementations, the disclosed antenna designs can balance additional capacitance and inductances in the antenna structure.

In some implementations, the antenna designs of the subject technology can be generated to withstand high stretch (e.g., greater than 10%) without cracking by sectioning the antennas into tightly capacitively coupled subsections, preventing damage under high tensile stress. In some implementations, multi-layered metallized elastomer antennas can form compact, wideband, flexible antennas through capacitively coupled element design in multiple dimensions resulting in bandwidth, reliability, and cost improvements over other methods and designs. In some implementations, the disclosed antennas can be designed such that the antenna maintains resonance at the specific design frequencies by designing one dimension to deform over stretch to maintain the primary resonance while other dimensions lose their resonance. In some implementations, impedance and aperture tuners can be used to provide additional resonance maintenance over stretch.

The disclosed technology is the first implementation of flexible, bendable, and stretchable antennas and circuitry built into elastomer via a modified LDS process and integrated with over-molded active electronics directly. Currently there is no known method to make reliable flexible, stretchable circuits and antennas in the industry, which are essential for wireless communications in augmented-reality (AR) systems involving wearable devices. The disclosed technology provides a robust high-volume solution and design space for future consumer electronic devices, including any company with AR ambitions, such as Google, Apple, Microsoft, and more. The disclosed technology is targeted at wearables including wristbands and glasses but could be applied to other wearable devices.

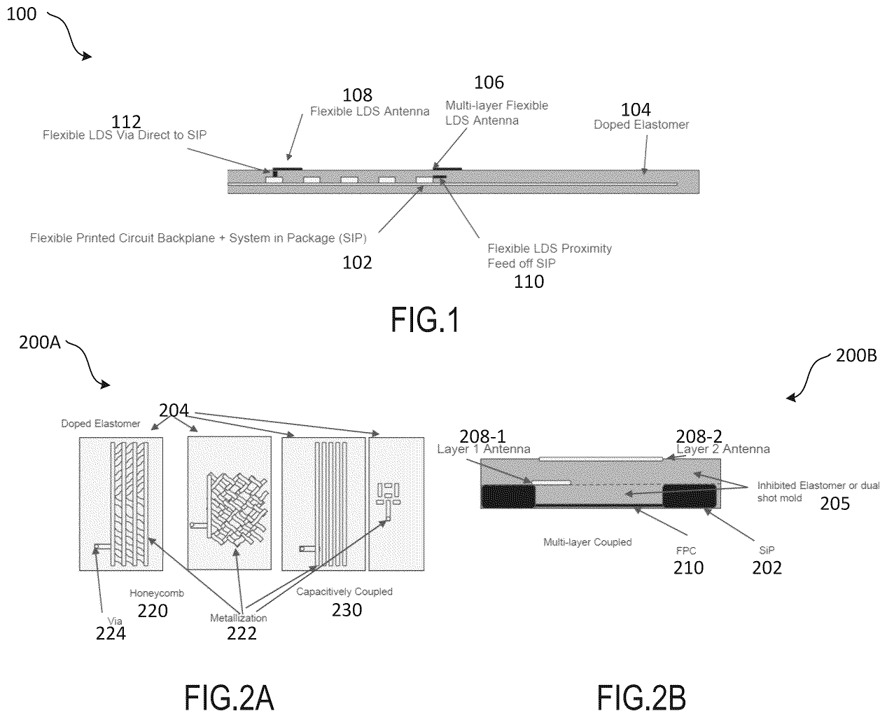

Turning now to the figures, FIG. 1 is a schematic diagram illustrating a cross-sectional view of an example of a stretchable multi-layer system 100, according to some aspects of the subject technology. In one embodiment, an FPC with various components and modules 102, such as chips or systems in packages, may be over-molded either fully or partially with a doped elastomer 104. The doped elastomer 104 may have one or more dopants formulated to deliver a range of electrical, thermal, and mechanical properties. The doped elastomer 104 may further be processed by laser light through laser direct sintering to convert one or more of the dopants to metal seeds. The doped laser processed elastomer 104 can be metallized by electroless plating or a combination of electroless and electroplating to form patterned metallized elastomeric structures, including flexible antennas 108. Flexible vias 112 can be further successfully developed by laser direct sintering and plating holes in the doped elastomer 104 created by molding operations, laser drilling, or mechanical drilling, among others. Multi-layer circuits and antennas 106 can be created through creating single layer structures, over-molding with an additional layer of doped elastomer 104, then repeating the developed process. Flexible via 112 may be used to connect between layers of metallized doped elastomer 104 if desired, or directly to system in package module, chips, or flexible printed circuits 102, among others. Additionally, multi-layer flexible antennas 106 may be created and fed via flexible feeds 110 created in the doped elastomer 104 through the multi-layer process described as a non-limiting example.

FIG. 2A and FIG. 2B are schematic diagrams illustrating a top view 200A and a cross-sectional view 200B of a section of the stretchable multi-layer system of FIG. 1, according to some aspects of the subject technology. Several methods of making flexible antennas in the doped elastomer 204 are shown in top view 200A, including but not limited to full antenna metallization, honeycomb metallization 220, crosshatch metallization 222, capacitively coupled strips 230, fed by via 224, proximity feed, aperture feed, or other feed structures. The cross section 200B shows a representative but non-limiting case of a multi-layered flexible antenna created in elastomer 205. The elastomer 205 can be produced in steps through multiple molding shots or inhibited elastomer application, where the doped elastomer 205 is laser direct sintered and plated before each new layer application. Antennas or circuits can be built on successive layers in an additive process this way, shown for demonstration purposes as layer 1 antenna 208-1 and layer 2 antenna 208-2 in the cross-sectional view 200B. Further, metallized layers such as layer 1 antenna 208-1 can be configured to connect directly to circuitry attached to the FPC 210 such as system in package 202.

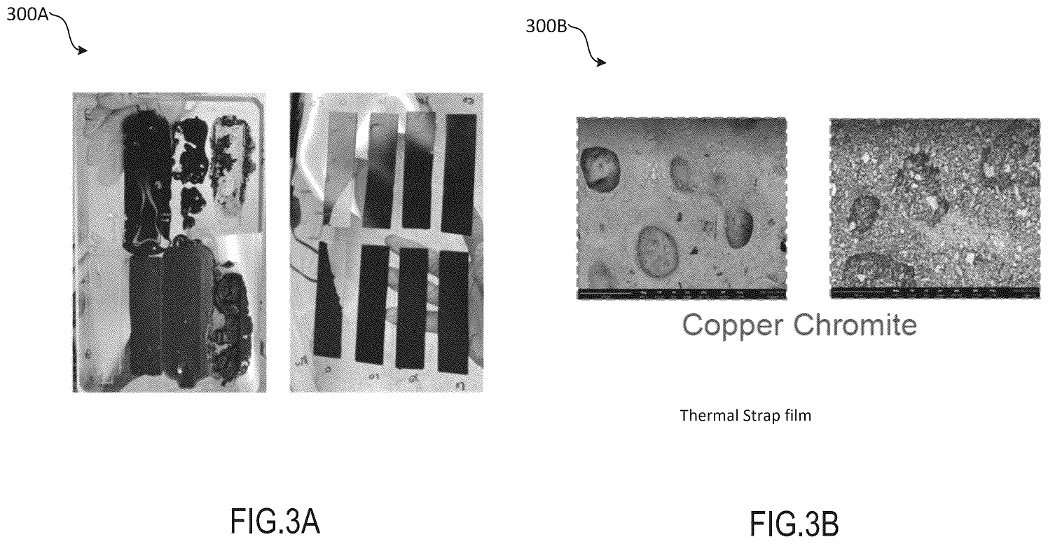

FIG. 3A and FIG. 3B are schematic diagrams illustrating top views 300A and 300B of an example of substrates produced by the subject technology showing effects of copper-chromite particle size on the curing process of the substrate. The substrates in 300A do not form and cure if the particle size is too large and must be optimized to get viscosities compatible with cast and cure, compression molding, or liquid injection molding processes. Further, the particle size must be optimized and mixed appropriately so that the substrate will cure properly. An example of proper particle size and dispersion versus too large of a dopant particle is shown in top view 300B, with substrate outcomes shown in the top view 300A.

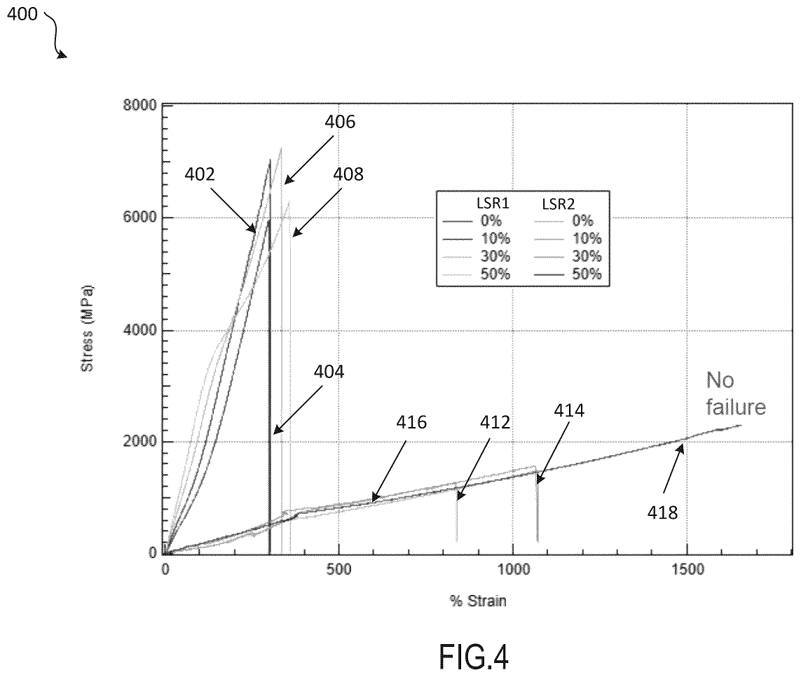

FIG. 4 is a chart illustrating the stress-strain relationship of two liquid silicone rubber (LSR) formulations with four different doping concentrations. The strain at break increases slightly for LSR 1 for 10% 402, 30% 406, and 50% 408 doping concentrations versus the undoped case 404. LSR 2 shows significant increases in strain at break due to doping concentration, where no failure was measured at over 1600% strain for the 50% doping case 418. Large increases in strain at break were observed over the undoped case 412, increasing for both 10% doping 414 and 30% doping 416 cases. In some instances, liquid silicone rubber mechanical properties can also be significantly enhanced through use of doping percentage.

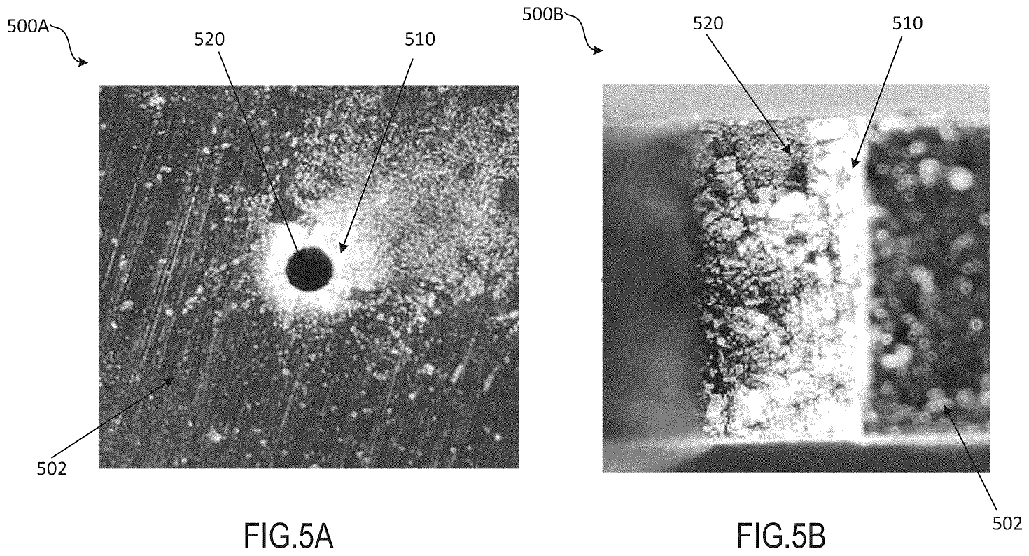

FIG. 5A and FIG. 5B are schematic diagrams illustrating cross-sectional views 500A and 500B of an elastomeric metallized via, according to some aspects of the subject technology. The via hole 510 can be created in the flexible doped elastomer 502 through laser drilling, mechanical drilling, or as a molded feature, among others. Additionally, very high aspect ratios of greater than 6:1 may be obtained through the use of UV drilling of the flexible doped elastomer 502. Via 520 is created by metallizing the via hole 510 on the inside of the via hole 510 as well as an annular ring on outer surfaces by laser activation and plating either by the UV laser used for drilling, or a separate laser that can be infrared, green, or other types of lasers, as long as power and exposure are correct. UV laser is preferred for high aspect ratios to activate the dopant in the sidewalls, but alternatives can be used.

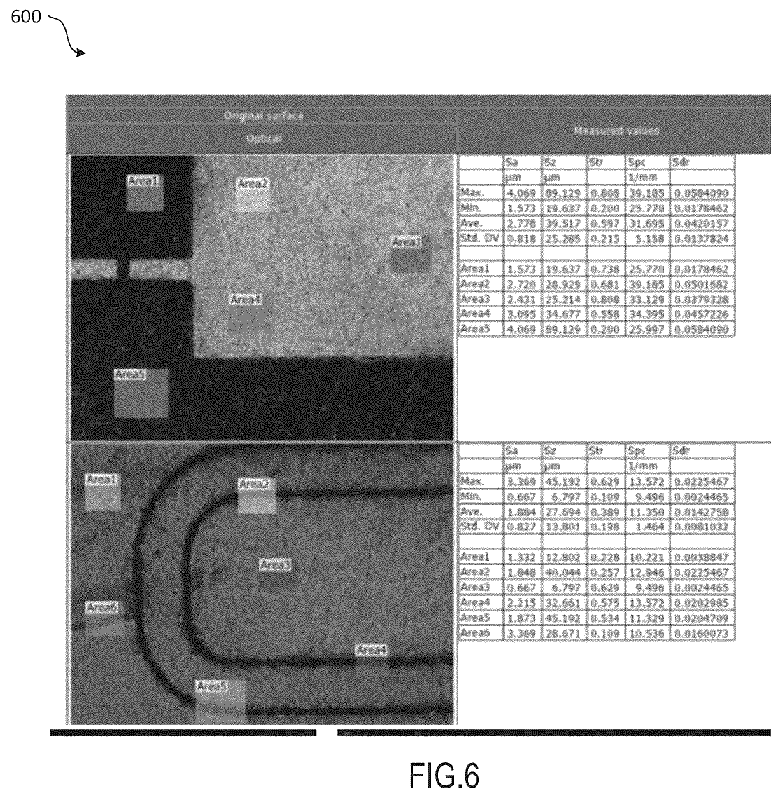

FIG. 6 is a schematic diagram illustrating surface texture 600 of an antenna and transmission line created in the subject technology, with example surface roughness shown post laser and plate for elastomer only and metallized elastomer regions.

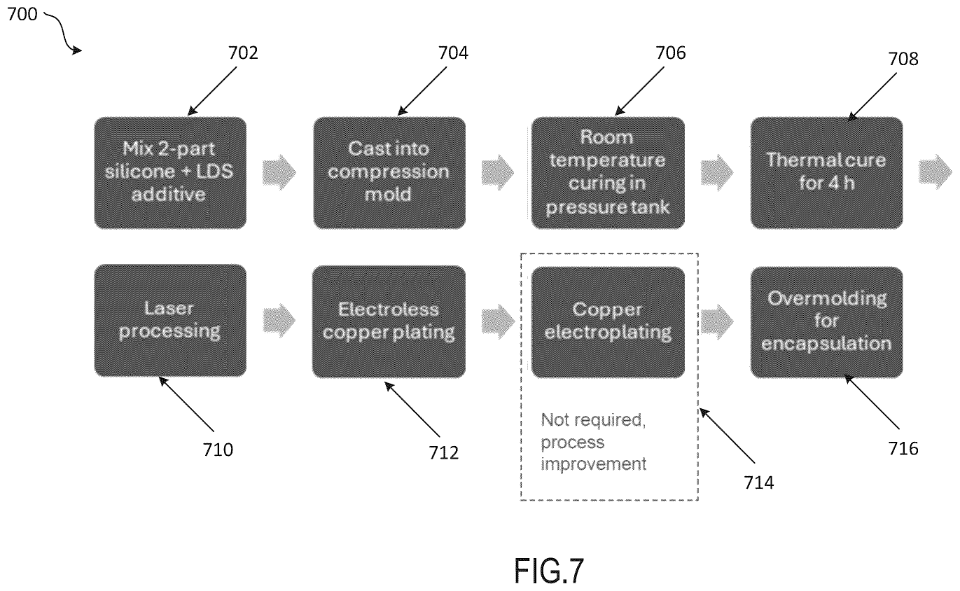

FIG. 7 is a flow diagram illustrating an example of a process 700 for providing of a stretchable multi-layer system, according to some aspects of the subject technology. Process 700 includes a number of process steps as described herein. In process step 702, the silicone parts A and B are thoroughly mixed with the dopant for optimum dispersion. Next, in process step 704, the mixture is cast, compressed, or injected into a mold to make a given shape. In process step 706, the molded material can optionally be cured in a pressure tank and then optionally thermally cured to reduce cure time. In process steps 706 and 708, one possible curing process is shown, which can be altered to allow for rapid compression or liquid injection molding by changing the pressure and temperature profile. The molded material is then patterned, in process step 710, by a laser beam of appropriate power to activate the dopant and create metal seeds. In process step 712, the molded part is then dipped in electroless copper plating solution to grow the initial metallization. The metallized part can continue to be plated to desired thickness using the process step 712 (e.g., electroless plating), or can be electroplated, in process step 714, to a desired thickness. In some implementations, during the process step 714, it is possible to generate a metal foil with lower stress concentrations and better ductility and strain performance. The metallized foil of desired thickness can be further electroless plated, in the process step 712, or electroplated, using the process step 714 with an additional non-copper passivation layer. The metallized elastomer part can be encapsulated, in process step 716, to protect the metallized surface and increase flexibility.

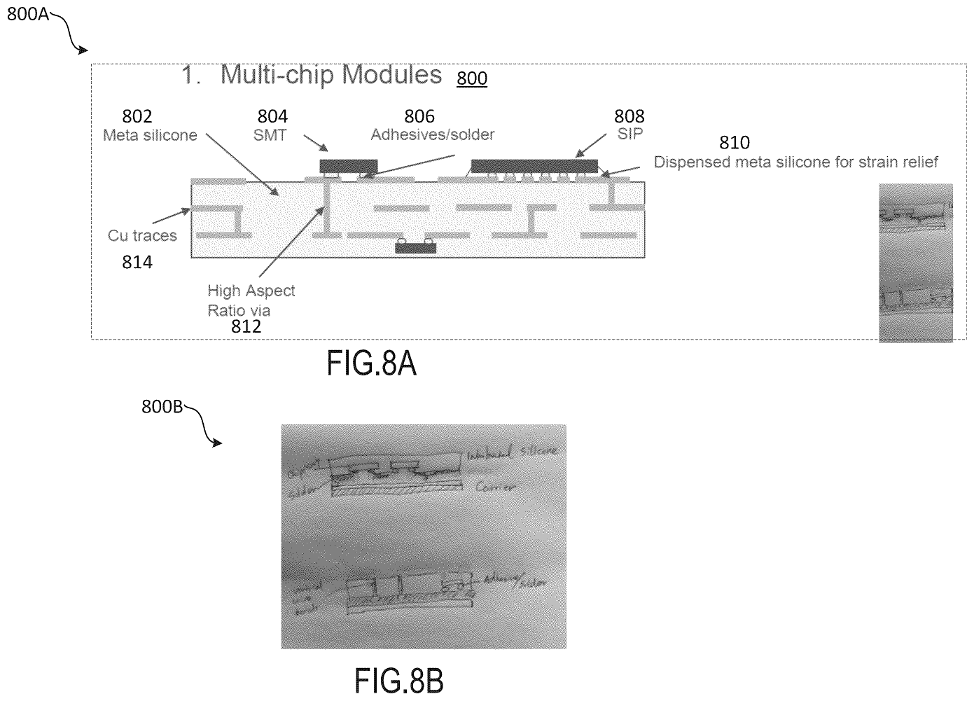

FIG. 8A and FIG. 8B are schematic diagrams illustrating two cross-section views 800A and 800B of a multi-layer elastomeric circuit with multiple chips and/or SiPs comprising a flexible module 800, according to some aspects of the subject technology. The multi-layer substrate is composed of doped silicone 802, with copper traces and pads 814 or alternative metallization formed through LDS and plating. Flexible high aspect ratio vias 812 are formed in the substrate through laser drilling or micro-molding, laser activation and/or plating. Surface-mount technology (SMT) chip modules 804 and SiP modules 808 are applied to the elastomeric metallized module via adhesives and/or solder 806 and further may be supported through underfill silicone for strain relief 810.

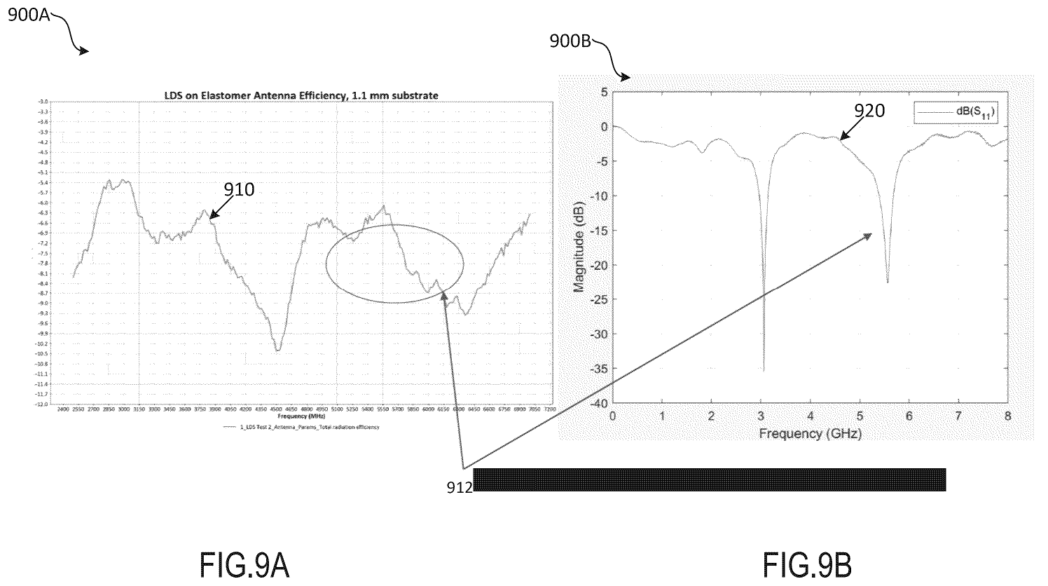

FIG. 9A and FIG. 9B are charts 900A and 900B illustrating plots 910 and 920 of antenna efficiency and the return loss of a fabricated edge fed patch antenna in the subject technology. The edge fed patch antenna is created on elastomeric substrate by laser activation using LDS of a metal seed layer, followed by electroless copper and optionally electroplated copper. The substrate in this example is quite thin, with a thickness of about 1.1 mm, but still shows high efficiency of over 25%, as indicated by plot 910, due to the low loss of the doped elastomeric material and metallization. The shifted resonances 912 in the plots 910 and 920 may be artifacts probably related to technical issues during measurement.

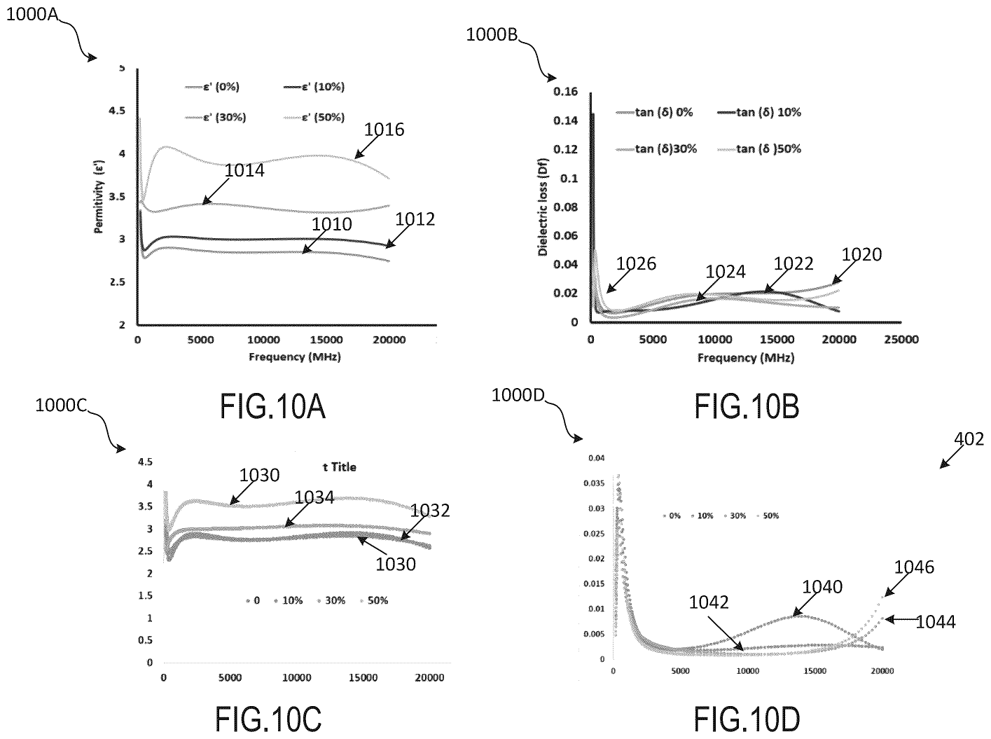

FIG. 10A, FIG. 10B, FIG. 10C and FIG. 10D are charts 1000A, 1000B, 1000C and 1000D illustrating plots of material permittivity and loss tangent over frequency for a range of doping levels, for two base liquid silicone rubber (LSR) formulations, according to some aspects of the subject technology. Plots 1010, 1012, 1014 and 1016, respectively, correspond to doping levels of 0%, 10%, 30% and 50%. The permittivity of LSR 1 formulation of chart 1000A is shown to be tunable and nearly flat across the commercial communications bands for plots 1010, 1012, 1014, and 1016, increasing with increasing doping for a full tuning range of 2.8 to 4.0 relative permittivity. The material loss tangent for LSR 1 formulation of chart 1000B is not linear and can be selected to optimize performance in certain frequency ranges. Plots 1020, 1022, 1024 and 1026 respectively correspond to doping levels of 0%, 10%, 30% and 50%. The material electromagnetic loss is shown in 1000B for this formulation to be minimum for 30% doping (plot 1024) for the commercial cellular mid high and ultra-high bands, while 10% doping (plot 1022) is lower loss for cellular low bands. Plots 1024 and 1026 (respectively corresponding to 30% and 50%) are significantly better above 10 GHz than in plot 1022 (10% doping level), while doping in general improves loss versus 0% doping (plot 1020).

It can be seen that the formulation can be optimized through doping for specific commercial technologies. LSR 2 formulation of chart 1000C shows similar permittivity trends but less tunability than LSR 1 formulation of 1000A, still showing increasing permittivity versus 0% doping (plot 1030) for 10% doping level (plot 1032), 30% doping level (plot 1034), and 50% doping level (plot 1030), for a full tuning range of approximately 2.9 to 3.5 relative permittivity. LSR 2 formulation shows ultra-low loss tangent chart 1000D versus LSR 1 formulation of chart 1000B that decreases with doping level compared to 0% (plot 1040), 10% (plot 1042) and 30% (plot 1044), but not 50% (plot 1046) doping levels. It can be seen from the loss tangent curves of chart 1000D of LSR 2 formulation that exceptionally low loss flexible RF material can be created from elastomeric substrates, but the doping level should be optimized for target frequency range.

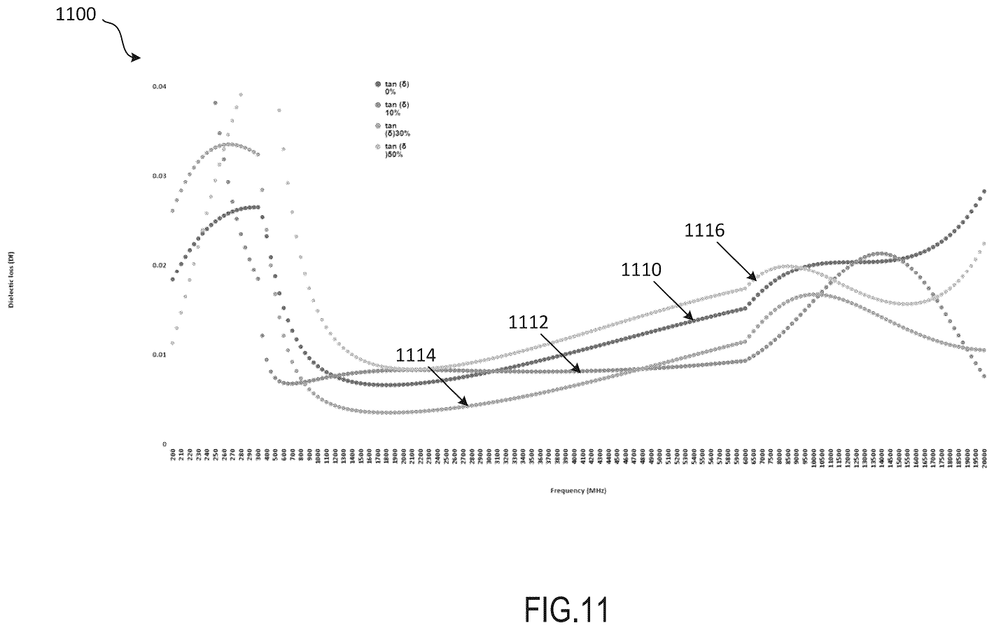

FIG. 11 is a chart 1100 illustrating plots 1110, 1112, 1114, and 1116 of dielectric loss versus frequency for doping levels of 0% (plot 1110), 10% (plot 1112), 30% (plot 1114), and 50% (plot 1116) for LSR 2 formulation, zoomed in. It is clear that 10% doping (plot 1112) is desirable for cellular low band antennas, while 30% (plot 1114) would be desirable for all other cellular bands below 5 GHz. Doping of 50% (plot 1116) actually raises the loss above that of the 0% doped material (plot 1110) and would not be desirable for wireless performance in this formulation. Different doping levels may be used according to product wireless operating targets.

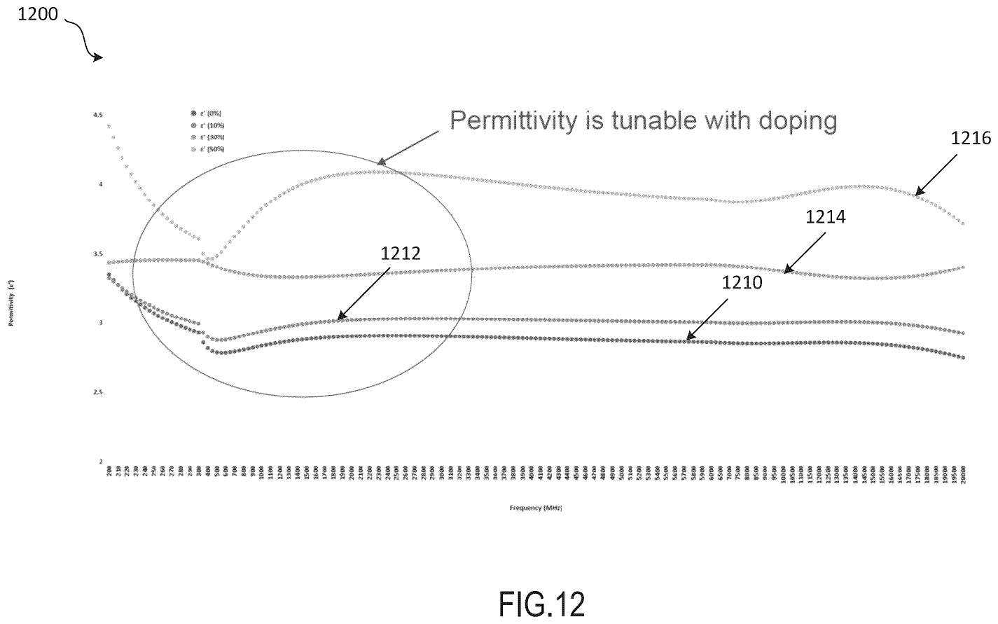

FIG. 12 is a chart 1200 illustrating plots 1210, 1212, 1214, and 1216 of permittivity versus frequency for doping levels of 0% (plot 1210), 10% (plot 1212), 30% (plot 1214), and 50% (plot 1216) for LSR 2 formulation, zoomed in. While permittivity generally increases with doping, 50% doping (plot 1216) shows that permittivity can become nonlinear past certain dopant loading levels.

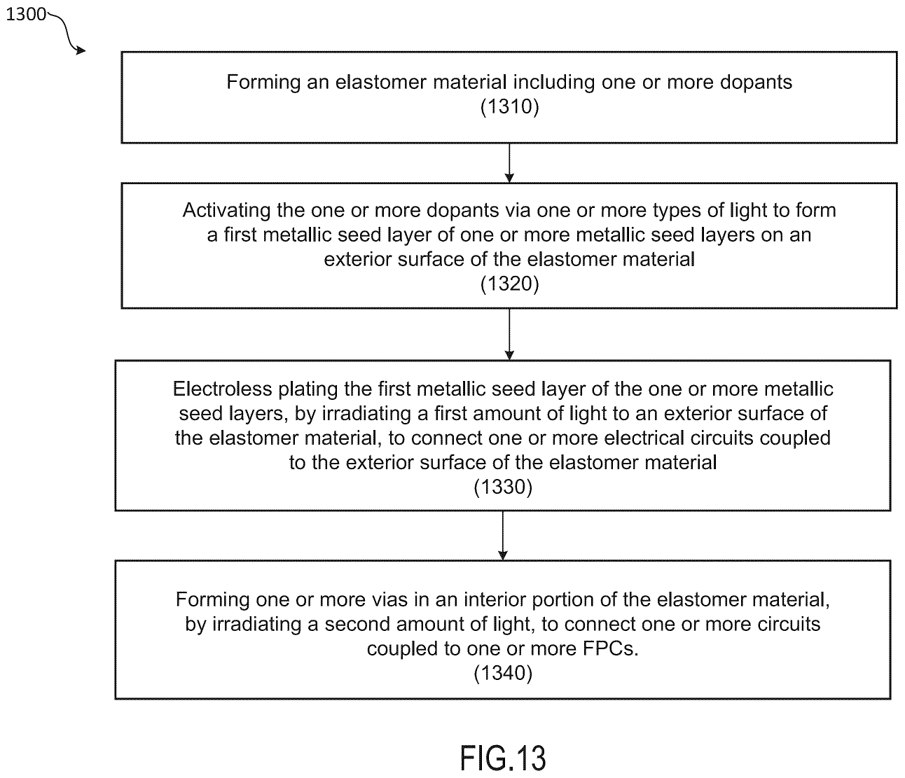

FIG. 13 is a flow diagram illustrating an example of a process 1300 for providing of a stretchable multi-layer system, according to some aspects of the subject technology. The process 1300 includes process steps 1310, 1320, 1330 and 1340 described below.

In process step 1310, an elastomer material including one or more dopants is formed.

In process step 1320, the one or more dopants are activated by types of light to form a first metallic seed layer of one or more metallic seed layers on an exterior surface of the elastomer material.

In process step 1330, the first metallic seed layer of the one or more metallic seed layers are electroless plated by irradiating a first amount of light to an exterior surface of the elastomer material to connect one or more electrical circuits coupled to the exterior surface of the elastomer material.

In process step 1340, one or more vias are formed in an interior portion of the elastomer material, by irradiating a second amount of light, to connect one or more circuits coupled to one or more FPCs.

An aspect of the subject technology is directed to a wearable device consisting of an FPC including an elastomer material and one or more dopants included in the elastomer material to be activated in response to being irradiated by light to cause formation of a first metallic seed layer on or under a surface of the elastomer material. The first metallic seed layer is configured to be electroless plated to form one or more electrical circuits or antennas.

In some implementations, the first metallic seed layer is further configured to form one or more vias in an interior portion of the elastomer material in response to receiving further light irradiation to connect one or more circuits on two or more layers or surfaces of the metallized elastomeric material, or to a surface pad of a flexible printed circuit (FPC), an integrated circuit (IC), system in a package (SiP), or one or more other electronic modules.

In one or more implementations, light comprises a laser light including infrared or ultra-violet (UV) light.

In some implementations, a three-dimensional (3-D) structure is formed in and on the elastomer material through successive layer formation and connection of layers through via formation or edge plating.

In some implementations, rendering the 3-D structure is performed by successive molding, cutting or ablating after formation of each metallization layer and interconnect.

In one or more implementations, the one or more electrical circuits comprise at least one or more antennas, filters or transmission lines.

In some implementations, additional dopants are added to tune and control material coefficient of thermal expansion (CTE) to allow multi-layer molding processes at standard process temperatures up to about 250 Celsius.

In one or more implementations, the one or more dopants comprise a simple or a mixed metal oxide containing copper which yields copper metal particles when incorporated into a polymer matrix and irradiated with laser radiation, wherein the mixed metal oxides include CuFe, CuAl, CuMn, CuCo, CuSn and CuCr families.

In some implementations, the laser radiation comprises laser lights with different wavelengths including ultra-violet (UV) light and infrared (IR) wavelengths.

In one or more implementations, the elastomer material comprises a dielectric material with tunable frequency, permittivity and dielectric loss to achieve desired antenna size, bandwidth and efficiency.

Another aspect of the subject technology is directed to a method comprising forming an elastomer material including one or more dopants and activating the one or more dopants via one or more types of light to form a first metallic seed on or under a surface of the elastomer material. The method also includes electroless plating the first metallic seed layer by irradiating a first amount of light to an exterior surface of the elastomer material, to connect one or more electrical circuits coupled to the exterior surface of the elastomer material. The method further includes forming one or more vias in an interior portion of the elastomer material, by irradiating a second amount of light, to connect one or more circuits coupled to one or more FPCs.

In some implementations, the method further comprises elaborating the elastomer material containing the one or more dopants or metallic circuits by over-molding with another layer of doped or undoped elastomer.

In one or more implementations, the method further comprises elaborating the elastomer material containing the one or more dopants or metallic circuits by over-molding with another layer of doped or undoped elastomer.

In some implementations, permittivity and dielectric loss properties of the elastomer material is tuned to a desired frequency by activating the one or more dopants.

In one or more implementations, the elastomer material is formed to withstand a high stretch greater than 10% without cracking by sectioning the one or more electrical circuits including antennas into tightly capacitively coupled subsections.

In some implementations, connecting the one or more electrical circuits comprises connecting at least one or more antennas, filters or transmission lines configuring the one or more circuits to maintain resonance at desired frequencies by allowing one dimension to deform over stretch to maintain a primary resonance while other dimensions lose their resonance.

Yet another aspect of the subject technology relates to an FPC including an elastomer material and/or more dopants included in the elastomer material and configured to be activated via one or more types of light to form a first metallic seed layer of one or more metallic seed layers on an exterior surface of the elastomer material. The first metallic seed layer of the one or more metallic seed layers is configured to be electroless plated, in response to receiving a first amount of light, to connect one or more electrical circuits coupled to the exterior surface of the elastomer material, and form one or more vias in an interior portion of the elastomer material, in response to receiving a second amount of light, to connect the one or more electrical circuits.

In one or more implementations, the elastomer material comprises dopant particles including copper chromide, and wherein a mean size of the dopant particles in the elastomer material is less than about 10 microns.

In some implementations, the elastomer material comprises a dielectric material with tunable characteristics to achieve a desired circuit size, bandwidth and efficiency, and wherein the elastomer material comprises liquid silicone rubber.

In some implementations, the word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” Pronouns in the masculine (e.g., his) include the feminine and neuter gender (e.g., her and its) and vice versa. The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public, regardless of whether such disclosure is explicitly recited in the above description. No clause element is to be construed under the provisions of 35 U.S.C. § 112, sixth paragraph, unless the element is expressly recited using the phrase “means for” or, in the case of a method clause, the element is recited using the phrase “step for.”

While this specification contains many specifics, these should not be construed as limitations on the scope of what may be described, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially described as such, one or more features from a described combination can in some cases be excised from the combination, and the described combination may be directed to a sub-combination or variation of a sub-combination.

The subject matter of this specification has been described in terms of particular aspects, but other aspects can be implemented and are within the scope of the following clauses. For example, while operations are depicted in the drawings in a particular order, this should not be understood as requiring that such operations be performed in the particular order shown or in sequential order, or that all illustrated operations be performed, to achieve desirable results. The actions recited in the clauses can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the clauses. In addition, in the detailed description, it can be seen that the description provides illustrative examples, and the various features are grouped together in various implementations for the purpose of streamlining the disclosure. The method of disclosure is not to be interpreted as reflecting an intention that the described subject matter requires more features than are expressly recited in each clause. Rather, as the clauses reflect, inventive subject matter lies in less than all features of a single disclosed configuration or operation. The clauses are hereby incorporated into the detailed description, with each clause standing on its own as a separately described subject matter.

As used herein, the phrase “at least one of” preceding a series of items, with the terms “and” or “or” to separate any of the items, modifies the list as a whole, rather than each member of the list (i.e., each item).

To the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A wearable device, comprising:
an elastomer material; and
one or more dopants included in the elastomer material and configured to be activated in response to light irradiation,
wherein,
the activation of the one or more dopants in the elastomer material is configured to cause forming of a first metallic seed layer on and under a surface of the elastomer material, and
the first metallic seed layer is configured to be electroless plated to form one or more electrical circuits or antennas.

2. The wearable device of claim 1, wherein the first metallic seed layer is further configured to form one or more vias in an interior portion of the elastomer material in response to receiving further light irradiation to connect one or more circuits on two or more layers or surfaces of the metallized elastomeric material, or to a surface pad of a flexible printed circuit (FPC), an integrated circuit (IC), system in a package (SiP), or one or more other electronic modules.

3. The wearable device of claim 1, wherein the light irradiation comprises using a laser light including infrared or ultra-violet (UV) light.

4. The wearable device of claim 1, wherein a three-dimensional (3-D) structure is formed in and on the elastomer material through successive layer formation and connection of layers through via formation or edge plating.

5. The wearable device of claim 4, wherein the 3-D structure is rendered by successive molding, cutting or ablating after formation of each metallization layer and interconnect.

6. The wearable device of claim 1, wherein the one or more electrical circuits comprise at least one or more antennas, filters or transmission lines.

7. The wearable device of claim 1, wherein additional dopants are added to tune and control material coefficient of thermal expansion (CTE) to allow multi-layer molding processes at standard process temperatures up to about 250 Celsius.

8. The wearable device of claim 1, wherein the one or more dopants comprise a simple or a mixed metal oxide containing copper which yields copper metal particles when incorporated into a polymer matrix and irradiated with laser radiation, wherein the mixed metal oxide include CuFe, CuAl, CuMn, CuCo, CuSn and CuCr families.

9. The wearable device of claim 8, wherein the laser radiation comprises laser lights with different wavelengths including ultra-violet (UV) light and infrared (IR) wavelengths.

10. The wearable device of claim 8, wherein an FPC, an IC, an SiP, or another electronic module is encased within a stretchable metallized elastomer.

11. The wearable device of claim 1, wherein the elastomer material comprises a dielectric material with tunable frequency, permittivity and dielectric loss to achieve desired antenna size, bandwidth and efficiency.

12. A method, comprising:
forming an elastomer material including one or more dopants;
activating the one or more dopants via one or more types of light to form a first metallic seed layer of one or more metallic seed layers on an exterior surface of the elastomer material;
electroless plating the first metallic seed layer of the one or more metallic seed layers, by irradiating a first amount of light to an exterior surface of the elastomer material, to connect one or more electrical circuits coupled to the exterior surface of the elastomer material; and
forming one or more vias in an interior portion of the elastomer material, by irradiating a second amount of light, to connect one or more circuits coupled to one or more FPCs.

13. The method of claim 12, further comprising:
elaborating the elastomer material containing the one or more dopants or metallic circuits by over-molding with another layer of doped or undoped elastomer; and
tuning mechanical strain handling and CTE to a desired value through a choice of one or more dopants and a percentage loading.

14. The method of claim 12, further comprising interconnecting the one or more metallic seed layers with other types of circuits including the FPCs.

15. The method of claim 12, wherein permittivity and dielectric loss properties of the elastomer material is tuned to a desired frequency range through dopant choice and percentage loading.

16. The method of claim 12, wherein the elastomer material is formed to withstand a high stretch greater than 10% without cracking by sectioning the one or more electrical circuits including antennas into tightly capacitively coupled subsections.

17. The method of claim 12, wherein:
connecting the one or more electrical circuits comprises connecting at least one or more antennas, filters or transmission lines; and
configuring the one or more circuits to maintain resonance at desired frequencies by allowing one dimension to deform over stretch to maintain a primary resonance while other dimensions experience resonance changes.

18. An FPC, comprising:
an elastomer material; and
one or more dopants included in the elastomer material and configured to be activated in response to light irradiation to cause formation of a first metallic seed layer on or under an exterior surface of the elastomer material, wherein the first metallic seed layer is configured to be electroless plated to form one or more electrical circuits or antennas.

19. The FPC of claim 18, wherein the elastomer material comprises dopant particles including one or more laser direct structuring (LDS) additives, and wherein a mean size of the dopant particles in the elastomer material is less than about 10 microns.

20. The FPC of claim 18, wherein the elastomer material comprises a dielectric material with tunable characteristics to achieve a desired circuit size, bandwidth and efficiency, and wherein the elastomer material comprises liquid silicone rubber.
